(19) United States
(12) Patent Application Publication
(10) Pub. No.: US 2018/0254288 A1
(43) Pub. Date: Sep. 6, 2018

(54) Self-Luminous Display Array Substrate and Using Method Thereof

(71) Applicant: Shanghai Oxi Technology Co., Ltd, Shanghai (CN)

(72) Inventors: Yan Ling, Shanghai (CN); Hong Zhu, Shanghai (CN)

(21) Appl. No.: 15/756,313

(22) PCT Filed: Feb. 15, 2017
(86) PCT No.: PCT/CN2017/073608

§ 371 Date: Feb. 28, 2018

(30) Foreign Application Priority Data
Aug. 18, 2016 (CN) 201610685817.6

(51) Int. Cl. H01L 27/12; G09G 3/3233; G09G 3/3275; G09G 3/3266; H01L 27/32

(52) U.S. Cl. CPC H01L 27/124; G09G 3/3233; H01L 27/3265; G09G 3/3266; H01L 27/3262; G09G 3/3275

(57) ABSTRACT

Self-luminous display array substrate and using method are provided. The substrate includes: first data lines; first scanning lines; pixel areas having pixels, each pixel includes a self-luminous circuit including a first TFT device and a self-luminous device, the first data lines are connected with source or drain of the first TFT device, the first scanning lines are connected with gate of the first TFT device, the substrate further includes second data lines and second scanning lines, the pixels have an optical fingerprint sensing circuit including a photosensitive device and a second TFT device, the photosensitive device includes first and second electrodes, the first electrode is connected with source or drain of the second TFT device, the second data lines are connected with drain or source of the second TFT device, the second scanning lines are connected with gate of the second TFT devices. Structures and functions of substrate are improved.

### CROSS-REFERENCE TO RELATED APPLICATIONS

This application claims the benefit of priority to Chinese Patent Application No. 201610685817.6, filed on Aug. 18, 2016, and entitled “SELF-LUMINOUS DISPLAY ARRAY SUBSTRATE AND USING METHOD THEREOF”, the entire disclosure of which are incorporated herein by reference.

### TECHNICAL FIELD

The present disclosure generally relates to photoelectric display field, and more particularly, to a self-luminous display array substrate and a using method thereof.

### BACKGROUND

Display panels are generally used to display output information of electronic is products. A display panel generally includes an array substrate. In all types of array substrate, self-luminous display array substrates are advantageous in weight, size and power consumption as not requiring a backlight source, and thus become an important development direction of the current array substrates.

However, structures and functions of existing self-luminous display array substrates need to be improved.

To improve the structures and functions of the existing self-luminous display array substrates, new design and optimization on the existing self-luminous display array substrates are needed.

### SUMMARY

In embodiments of the present disclosure, a self-luminous display array substrate and a using method thereof are provided with improved structures, functions and performance.

In an embodiment of the present disclosure, a self-luminous display array substrate is provided, including: a plurality of first data lines; and a plurality of first scanning lines, wherein the plurality of first data lines and the plurality of first scanning lines intersect to form a plurality of pixel areas which have pixels disposed therein, each pixel includes a self-luminous circuit which includes at least one first TFT device and at least one self-luminous device, the first data lines are electrically connected with a source or a drain of at least one of the first TFT devices, and the first scanning lines are electrically connected with a gate of at least one of the first TFT devices, wherein the self-luminous display array substrate further includes a plurality of second data lines and a plurality of second scanning lines, at least a portion of the pixels have an optical fingerprint sensing circuit which includes at least one photosensitive device and at least one second TFT device, the photosensitive device includes a first electrode and a second electrode, the first electrode is electrically connected with a source or a drain of one second TFT device, the second data lines are electrically connected with a drain or a source of one second. TFT device, and the second scanning lines are electrically connected with a gate of at least one of the second TFT devices.

Optionally, the self-luminous display array substrate may further include a storage capacitor which is connected with the photosensitive device in parallel and a common electrode line, wherein one electrode of the storage capacitor and the first electrode of the photosensitive device are electrically connected with the source or the drain of the one second TFT device, and the other electrode of the storage capacitor and the second electrode of the photosensitive device are electrically connected with the common electrode line.

Optionally, the self-luminous display array substrate may further include a common electrode line, a power line, a ground line and a storage capacitor, wherein the second electrode of the photosensitive device is electrically connected with the common electrode line, one electrode of the storage capacitor and the first electrode of the photosensitive device are electrically connected with the source or the drain of the one second TFT device, and the other electrode of the storage capacitor is electrically connected with the power ne or the ground line.

Optionally, light emitted from the self-luminous circuit serves as light for fingerprint acquisition of the optical fingerprint sensing circuit.

In another embodiment of the present disclosure, a self-luminous display array substrate is provided, including: a plurality of first data lines; and a plurality of scanning lines, wherein the plurality of first data lines and the plurality of scanning lines intersect to form a plurality of pixel areas which have pixels disposed therein, each pixel includes a self-luminous circuit which includes at least one first TFT device and at least one self-luminous device, the first data lines are electrically connected with a source or a drain of at least one of the first TFT devices, and the scanning lines are electrically connected with a gate of at least one of the first TFT devices, wherein the self-luminous display array substrate further includes a plurality of second data lines, at least a portion of the pixels have an optical fingerprint sensing circuit which includes at least one photosensitive device and at least one second TFT device, the photosensitive device includes a first electrode and a second electrode, the first electrode is electrically connected with a source or a drain of one second TFT device, the second data lines are electrically connected with a drain or a source of one second TFT device, and the scanning lines are electrically connected with a gate of at least one of the second TFT devices.

Optionally, the self-luminous display array substrate may further include a storage capacitor which is connected with the photosensitive device in parallel and a common electrode line, wherein one electrode of the storage capacitor and the first electrode of the photosensitive device are electrically connected with the source or the drain of the one second TFT device, and the other electrode of the storage capacitor and the second electrode of the photosensitive device are electrically connected with the common electrode line.

Optionally, the self-luminous display array substrate may further include a common electrode line, a power line, a ground line and a storage capacitor, wherein the second electrode of the photosensitive device is electrically connected with the common electrode line, one electrode of the storage capacitor and the first electrode of the photosensitive device are electrically connected with the source or the drain of the one second TFT device, and the other electrode of the storage capacitor is electrically connected with the power line or the ground line.

Optionally, light emitted from the self-luminous circuit serves as light for fingerprint acquisition of the optical fingerprint sensing circa

In an embodiment of the present disclosure, a using method of the above self-luminous display array substrate is provided, wherein the first data lines and the scanning lines are used to perform refresh for display signal to the self-luminous circuit, and the second data lines and the scanning lines are used to acquire fingerprint image data from the optical fingerprint sensing circuit.

In another embodiment of the present disclosure, a self-luminous display array substrate is provided, including: a plurality of data lines; and a plurality of first scanning lines, wherein the plurality of data lines and the plurality of first scanning lines intersect to form a plurality of pixel areas which have pixels disposed therein, each pixel includes a self-luminous circuit which includes at least one first TFT device and at least one self-luminous device, the data lines are electrically connected with a source or a drain of at least one of the first TFT devices, and the first scanning lines are electrically connected with a gate of at least one of the first TFT devices, wherein the self-luminous display array substrate further includes a plurality of second scanning lines, at least a portion of the pixels have an optical fingerprint sensing circuit which includes at least one photosensitive device and at least one second TFT device, the photosensitive device includes a first electrode and a second electrode, the first electrode is electrically connected with a source or a drain of one second TFT device, the data lines are electrically connected with a drain or a source of one second TFT device, and the second scanning lines are electrically connected with a gate of at least one of the second TFT devices.

Optionally, the self-luminous display array substrate may further include a storage capacitor which is connected with the photosensitive device in parallel and a common electrode line, wherein one electrode of the storage capacitor and the first electrode of the photosensitive device are electrically connected with the source or the drain of the one second TFT device, and the other electrode of the storage capacitor and the second electrode of the photosensitive device are electrically connected with the common electrode line.

Optionally, the self-luminous display array substrate may further include a common electrode line, a power line, a ground line and a storage capacitor, wherein the second electrode of the photosensitive device is electrically connected with the common electrode line, one electrode of the storage capacitor and the first electrode of the photosensitive device are electrically connected with the source or the drain of the one second TFT device, and the other electrode of the storage capacitor is electrically connected with the power line or the ground line.

Optionally, light emitted from the self-luminous circuit serves as light for fingerprint acquisition of the optical fingerprint sensing circuit.

In another embodiment of the present disclosure, a using method of the above self-luminous display array substrate is provided, wherein the data lines and the first scanning lines are used to perform once refresh for display signal to a portion of the self-luminous circuits, and then the data lines and the second scanning lines are used to acquire fingerprint image data from a portion of the optical fingerprint sensing circuits; or the data lines and the second scanning lines are used to acquire fingerprint image data from a portion of the optical fingerprint sensing circuits, and then the data lines and the first scanning lines are used to perform once refresh for display signal to a portion of the self-luminous circuits.

In another embodiment of the present disclosure, a using method of the above self-luminous display array substrate is provided, wherein the data lines and the first scanning lines are used to perform at least once refresh for display signal to all the self-luminous circuits , and then the data lines and the second scanning lines are used to acquire fingerprint image data from all the optical fingerprint sensing circuits.

Embodiments of the present disclosure may provide following advantages. In embodiments of the present disclosure, the self-luminous circuit and the optical fingerprint sensing circuit are disposed in the same pixel (i.e., disposed in the same pixel area), and the self-luminous device in the self-luminous circuit is electrically connected with the first data lines and the first scanning lines via the corresponding first TFT device, and the photosensitive device in the optical fingerprint sensing circuit is electrically connected with the second data lines and the second scanning lines via the second ITT device, so that the self-luminous display array substrate not only supports a display function, but also can acquire a fingerprint image pressed on a display screen which is provided with the self-luminous display array substrate based on optical principle. That is, the self-luminous display array substrate can be used to acquire the fingerprint image. In this way, functions and an integration level of the self-luminous display array substrate may he increased.

Further, in the self-luminous display array substrate, the storage capacitor connected in parallel with the photosensitive device is disposed. In this way, equivalent capacitance of the photosensitive device is increased, and thus full well capacity the photosensitive device can reach becomes larger, and photoelectric data the photosensitive device can store becomes more, that is, the amount of photoelectric signals the photosensitive device can store is greater. Therefore, the photosensitive device may acquire more light information, a contrast ratio of fingerprint images may be increased, and the acquired fingerprint images may have better quality.

Further, in the self-luminous display array substrate, the other electrode of the storage capacitor and the second electrode of the photosensitive device are together electrically connected with the common electrode line. The common connection with the common electrode line may make their parallel effect more stable and electronic noise be less.

Further, the light emitted from the self-luminous circuit serves as the light for fingerprint acquisition of the optical fingerprint sensing circuit, so that no extra light source needs to be configured for the optical fingerprint sensing circuit, which may save cost and simplify structures.

### BRIEF DESCRIPTION OF THE DRAWINGS

FIG. 1 schematically illustrates a partial top view of a self-luminous display array substrate according to an embodiment;

FIG. 2 schematically illustrates a partial top view of a self-luminous display array substrate according to an embodiment;

FIG. 3 schematically illustrates a partial top view of a self-luminous display array substrate according to an embodiment;

FIG. 4 schematically illustrates a partial top view of a self-luminous display array substrate according to an embodiment; and

FIG. 5 schematically illustrates a partial top view of a self-luminous display array substrate according to an embodiment.

### DETAILED DESCRIPTION

As described in the background, functions and structures of existing self-luminous display array substrate need to be improved.

Therefore, embodiments of the present disclosure provide a self-luminous display array substrate. By disposing an optical fingerprint sensing circuit in a portion of pixels or in all pixels, functions of the self-luminous display array substrate may be strengthened, a structure of the self-luminous display array substrate may be improved, and an integration level of the self-luminous display array substrate may be increased.

In order to clarify the object, characteristic and advantages of embodiments of the present disclosure, embodiments of present disclosure will be described clearly in detail in conjunction with accompanying drawings.

In an embodiment, a self-luminous display array substrate is provided.

Referring to FIG. 1, FIG. 1 schematically illustrates a partial top view of a self-luminous display array substrate according to an embodiment. The self-luminous display array substrate includes a plurality of first data lines 111 and a plurality of first scanning lines 121. In FIG. 1, two first data lines 111 and two first scanning lines 121 are illustrated for representation. The first data lines 111 and the first scanning lines 121 extend along different axial directions, as shown in FIG. 1.

In some embodiments, the plurality of first data lines are parallel with each other, and the plurality of first scanning lines are parallel with each other. Therefore, in FIG. 1, the first data lines 111 are parallel with each other, and the first scanning lines 121 are parallel with each other.

It should be noted that, the self-luminous display array substrate generally includes a substrate, and the first datalines, the first scanning lines and other structures mentioned in the below embodiments are all formed on a surface of the substrate. The substrate is not shown in any figures.

Still referring to FIG. 1, the first data lines 111 and the first scanning lines 121 intersect to form a plurality of pixel areas (not labeled). In FIG. 1, one pixel area is illustrated, which is formed by the intersection of the two first data lines 111 and the two first scanning lines 121. In some embodiments, the first data lines 111 and the first scanning lines 121 may intersect with each other perpendicularly, so that the pixel area appears a rectangular shape (for example, a square shape) from a top view.

Still referring to FIG. 1, the pixel area has pixels (not labeled) disposed therein. The pixel includes a self-luminous circuit (not labeled) which includes four first TFT devices (not shown) and one self-luminous device (not shown).

It should be noted that, in FIG. 1, the first TFT device and the self-luminous device are not presented independently, but are uniformly illustrated as one display pixel function block 130. In addition to including the first TFT devices and the self-luminous device, the display pixel function block 130 may further include a capacitor structure, a routing circuit structure and the like.

In some embodiments, the display pixel function block 130, the first data lines 111, the first scanning lines 111, a power line 150 (described below), a ground line 160 (described below), and connection lines among them belong to the self-luminous circuit.

A source (or a drain) of one of the first TFT devices is electrically connected with the first data lines 111. A drain (or a source) of one of the first TFT devices is electrically connected with the self-luminous device. The first scanning line 121 is electrically connected with gates of three of the first TFT devices. Through the above electrical connections, the first data lines 111 and the first scanning line 121 can be used to perform refresh for display signal to the self-luminous circuit.

In some embodiments, the self-luminous circuit may include more than one first TFT devices or more than two self-luminous devices. In this case, the first data lines are electrically connected with a source or a drain of at least one of the first TFT devices, the self-luminous devices are electrically connected with a drain or a source of one of the first TFT devices, the first scanning lines are electrically connected with a gate of at least one of the first TFT devices. A circuit constructed by relatively few first TFT devices makes the self-luminous circuit simple and have low cost and high yield. A circuit constructed by relatively many first TFT devices makes the whole self-luminous circuit have better performance and be more stable. Therefore, in some embodiments, the self-luminous circuit may include a 1T (one first TFT device) or a 5T (five first TFT devices) structure.

In some embodiments, the self-luminous device may be an OLED luminous device. In this case, the self-luminous display array substrate may further be an active matrix array substrate of an OLED.

Still referring to FIG. 1, the self-luminous display array substrate further includes a plurality of second data lines 112 and a plurality of second scanning lines 122. One second data line 112 and one second scanning line 122 are shown in FIG. 1 for representation.

In some embodiments, the second data line 112 is disposed in parallel with the first data lines 111, and the second scanning line 122 is disposed in parallel with the first scanning line 121.

Still referring to FIG. 1, in some embodiments, an optical fingerprint sensing circuit (not labeled) may be further disposed in at least a portion of the pixels. The pixels in the pixel area shown in FIG. 1 have the optical fingerprint sensing circuit disposed therein.

The optical fingerprint sensing circuit includes a photosensitive device 170 and a second. TFT device 180. The photosensitive device 170 includes a first electrode (not labeled) and a second electrode (not labeled). The first electrode of the photosensitive device 170 is electrically connected with a source (or a drain) of the second TFT device 180. The second data line 112 is electrically connected with the drain (or the source) of the second TFT device 180. The second scanning line 122 is electrically connected with the gate of the second TFT device 180.

In some embodiments, the photosensitive device 170 may be a photodiode made of amorphous silicon, polycrystalline silicon, amorphous silicon germanium, amorphous germanium, polycrystalline germanium, polycrystalline germanium or an organic semiconductor. The photodiode may be a PIN photodiode or a PN photodiode, and thus the first and second electrodes are the two electrodes of the photodiode, respectively.

In some embodiments, the second data line 112 and the second scanning line 122 may be disposed based on arrangement of the pixels where the optical fingerprint sensing circuit is located. For example, when only pixels in odd rows (or even rows) have optical fingerprint sensing circuits, the second scanning line 122 may to be disposed in every two rows.

In some embodiments, the optical fingerprint sensing circuit may include at least one photosensitive device and at least one second TFT device. The optical fingerprint sensing circuit including a plurality of second TFT devices may have better electrical performance and cause better image signals. The optical fingerprint sensing circuit including a plurality of photosensitive devices may cause fingerprint images acquired by the optical fingerprint sensing circuit to have a higher resolution, which is more suitable for a case that an area of a single pixel area is relatively large, for example, the area of the pixel area is above 70 μm×70 μm.

In some embodiments, as the first electrode of the photosensitive device 170 is electrically connected with the source (or the drain) of the second TFT device 180, the second data line 112 is electrically connected with the drain (or the source) of the second TFT device 180, and the second scanning line 122 is electrically connected with the gate of the second TFT device 180. Therefore, the entire photosensitive device 170 can form an electrical connection structure with the second data line 112 and the second scanning line 122 via the second. TFT device 180, and fingerprint photoelectric signals generated by the photosensitive device 170 can be transmitted to an external chip via the second data line 112 and the second scanning line 122, so as to realize fingerprint image acquisition.

In some embodiments, when there are a plurality of second TFT devices, the first electrode of the photosensitive device is electrically connected with a source or a drain of one of the second TFT devices, the second data lines are electrically connected with a drain or a source of at least one of the second. TFT devices, and the second scanning lines are electrically connected with a gate of at least one of the second TFT devices. As described above, the optical fingerprint sensing circuit including a plurality of second TFT devices may have better electrical performance and cause better image signals.

Still referring to FIG. 1, the self-luminous display array substrate further includes a storage capacitor 190 which is connected in parallel with the photosensitive device 170. The storage capacitor 190 is a capacitor structure (usually a capacitor structure of a flat-plate capacitor model) and thus usually includes two electrodes as well. One electrode of the storage capacitor 190 together with the first electrode of the photosensitive device 170 is electrically connected with the source or the drain of the second TFT device 180.

Still referring to FIG. 1, the self-luminous display array substrate further includes a common electrode line 140. The other electrode of the storage capacitor 190 together with the second electrode of the photosensitive device 170 is electrically connected with the common electrode line 140, and the second electrode of the photosensitive device 170 is electrically connected with the common electrode line 140, so that the photosensitive device 170 can be biased with a negative voltage using the common electrode line 140, i.e., the photosensitive device 170 is reversely biased.

From above, the photosensitive device 170, the second TFT device 180, the storage capacitor 190, the second data lines 112, the second scanning lines 122, the common electrode line 140 and connection lines among them belong to the optical fingerprint sensing circuit.

Still referring to FIG. 1, the self-luminous display array substrate further includes a power line 150 and a ground line 160. Corresponding structures (not specifically shown in FIG. 1) of the display pixel function block 130 are respectively electrically connected with the power line 150 and the ground line 160. The power line 150 and the ground line 160 provide power and ground for the self-luminous device (i.e., provide positive and negative voltages to the self-luminous device). The self-luminous circuit controls a current flowing through the self-luminous device (or a voltage applied to the self-luminous device) based on an input display signal to control light emission intensity of the self-luminous device. That is, after refresh for display signal is performed to the self-luminous circuit by using the first data lines 111 and the first scanning lines 121, if different display signals are input, the self-luminous circuit causes the current flowing through the self-luminous device (or the voltage applied to the self-luminous device) to be different, so that the light emission intensity of the self-luminous device is different.

In the self-luminous display array substrate provided in the embodiments, the self-luminous circuit and the optical fingerprint sensing circuit are disposed in the same pixel (i.e., disposed in the same pixel area), and the self-luminous device in the self-luminous circuit is electrically connected with the first data lines 111 and the first scanning lines 121 via the first ITT device, and the photosensitive device 170 in the optical fingerprint sensing circuit is electrically connected with the second data lines 112 and the second scanning lines 122 via the second TFT device 180, so that the self-luminous display array substrate does not only support a display function, but also can acquire a fingerprint image pressed on a display screen which is provided with the self-luminous display array substrate based on optical principle. That is, the self-luminous display array substrate can be used to acquire the fingerprint image.

In this way, functions and an integration level of the self-luminous display array substrate may be increased.

Further, in the self-luminous display array substrate provided in the embodiments, the light emitted from the self-luminous circuit can also be used as the light for fingerprint acquisition of the optical fingerprint sensing circuit, so that no extra light source needs to be configured for the optical fingerprint sensing circuit, which may save cost and simplify structures. It should be noted that in this structure, a light shielding layer (not shown) may be disposed between the photosensitive device 170 and the self-luminous device to prevent a situation that “the light of the self-luminous device reaches the photosensitive device 170 before reaching a contact interface. The contact interface is an interface defined by a surface pressed by a finger and the finger itself.

Further, in the self-luminous display array substrate, the storage capacitor 190 connected in parallel with the photosensitive device 170 is disposed. In this way, equivalent capacitance of the photosensitive device 170 is increased, and thus full well capacity the photosensitive device 170 can reach becomes larger, and the amount of charge signals the photosensitive device 170 can store is greater. Therefore, the photosensitive device 170 may acquire more light information, a contrast ratio of fingerprint images may be increased, and the acquired fingerprint images may have better quality.

Further, in the self-luminous display array substrate, the other electrode of the storage capacitor 190 and the second electrode of the photosensitive device 170 are together electrically connected with the common electrode line 140. The common connection with the common electrode line 140 may make their parallel effect more stable and electronic noise be less.

In an embodiment, another self-luminous display array substrate is provided.

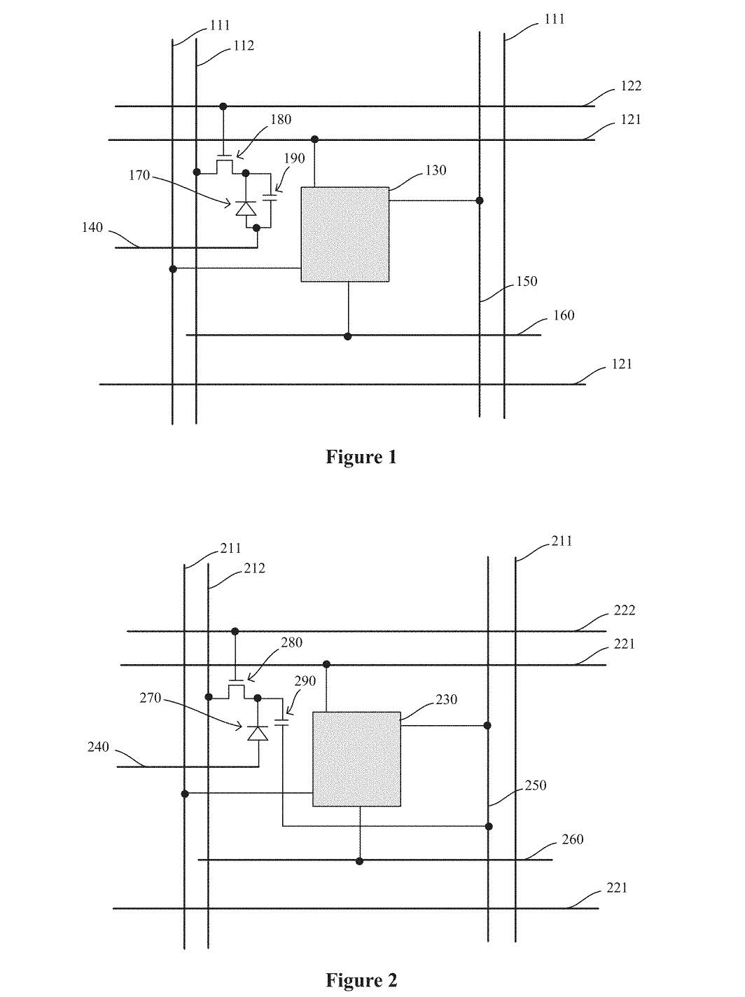

Referring to FIG. 2, FIG. 2 schematically illustrates a partial top view of a self-luminous display array substrate according to an embodiment. The self-luminous display array substrate includes a plurality of first data lines 211 and a plurality of first scanning lines 221. In FIG. 2, two first data lines 211 and two first scanning lines 221 are illustrated for representation. The first data lines 211 and the first scanning lines 221 extend along different axial directions, as shown in FIG. 2.

In some embodiments, as shown in FIG. 2, the two first data lines 211 are parallel with each other, and the two first scanning lines 221 are parallel with each other.

Still referring to FIG. 2, the first data lines 211 and the first scanning lines 221 intersect to form a plurality of pixel areas (not labeled). In FIG. 2, one pixel area is illustrated, which is formed by the intersection of the two first data lines 211 and the two first scanning lines 221.

Still referring to FIG. 2, the pixel area has pixels (not labeled) disposed therein. The pixel includes a self-luminous circuit (not labeled) which includes a plurality of first TFT devices (not shown) and one self-luminous device (not shown).

It should be noted that, in FIG. 2, the first TFT device and the self-luminous device are not presented independently, but are uniformly illustrated as one display pixel function block 230.

In some embodiments, the display pixel function block 230, the first data lines 211, the first scanning lines 221, a power line 250, a ground line 260, and connection lines among them belong to the self-luminous circuit.

A source (or a drain) of one of the first TFT devices is electrically connected with the first data lines 211. A drain (or a source) of one of the first TFT devices is electrically connected with the self-luminous device. The first scanning line 221 is electrically connected with a gate of at least one of the first TFT devices. Through the above electrical connections, the first data lines 211 and the first scanning line 221 can be used to perform refresh for display signal to the self-luminous circuit.

Still referring to FIG. 2, the self-luminous display array substrate further includes a plurality of second data lines 212 and a plurality of second scanning lines 222. One second data line 212 and one second scanning line 222 are shown in FIG. 2 for representation.

In some embodiments, the second data line 212 is disposed in parallel with the first data lines 211, and the second scanning line 222 is disposed in parallel with the first scanning line 221.

Still referring to FIG. 2, in some embodiments, an optical fingerprint sensing circuit (not labeled) may be further disposed in at least a portion of the pixels. The pixels in the pixel area shown in FIG. 2 have the optical fingerprint sensing circuit disposed therein.

The optical fingerprint sensing circuit includes a photosensitive device 270 and a second TFT device 280 The photosensitive device 270 includes a first electrode (not labeled) and a second electrode (not labeled). The first electrode of the photosensitive device 270 is electrically connected with a source (or a drain) of the second TFT device 280. The second data line 212 is electrically connected with the drain (or the source) of the second ITT device 280. The second scanning line 222 is electrically connected with the gate of the second TFT device 280.

In some embodiments, the photosensitive device 270 may be a PIN photodiode or a PN photodiode, and thus the first and second electrodes are the two electrodes of the photodiode, respectively.

Still referring to FIG. 2, the self-luminous display array substrate further includes a common electrode line 240, a power line 250 and a ground line 260. The second electrode of the photosensitive device 270 is electrically connected with the common electrode line 240. Corresponding structures of the display pixel function block 230 are respectively electrically connected with the power line 250 and the ground line 260.

Still referring to FIG. 2, the self-luminous display array substrate further includes a storage capacitor 290. One electrode of the storage capacitor 290 together with the first electrode of the photosensitive device 270 is electrically connected with the source or the drain of the second TFT device 280. The other electrode of the storage capacitor 290 is electrically connected with the power line 250. In some embodiments, the power line 250 in the self-luminous circuit serves as a common electrode of the storage capacitor (i.e., the power line 250 is used to provide a constant potential to a pole of the storage capacitor 290).

In the self-luminous display array substrate provided in the embodiments, the other electrode of the photosensitive device 270 is electrically connected with the cot non electrode line 240, and the other electrode of the storage capacitor 290 is is electrically connected with the power line 250, which simplifies a connection structure of the storage capacitor, facilitates connection between different wires, and simplifies design.

From above, the photosensitive device 270, the second TFT device 280, the storage capacitor 290, the second data lines 212, the second scanning lines 222, the power line 250, and connection lines among them belong to the optical fingerprint sensing circuit. The power line 250 is shared by the optical fingerprint sensing circuit and the self-luminous circuit. Therefore, it does not only provide power for the self-luminous device of the self-luminous circuit but also provides a constant potential to a pole of the storage capacitor 290.

More details about structures, properties and advantages of the self-luminous display array substrate can be found in the above descriptions of the foregoing embodiments.

In an embodiment, another self-luminous display array substrate is provided.

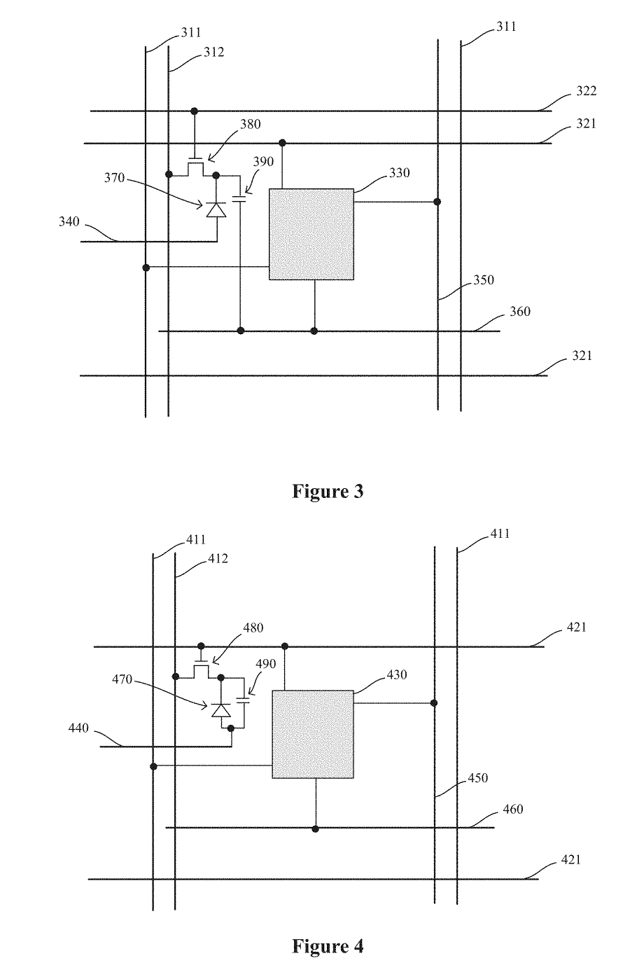

Referring to FIG. 3, FIG. 3 schematically illustrates a partial top view of a self-luminous display array substrate according to an embodiment. The self-luminous display array substrate includes a plurality of first data lines 311 and a plurality of first scanning lines 321. In FIG. 3, two first data lines 311 and two first scanning lines 321 are illustrated for representation. The first data lines 311 and the first scanning lines 321 extend along different axial directions, as shown in FIG. 3.

In some embodiments, as shown in FIG. 3, the two first data lines 311 are parallel with each other, and the two first scanning lines 321 are parallel with each other.

Still referring to FIG. 3, the first data lines 311 and the first scanning lines 321 intersect to form a plurality of pixel areas (not labeled). In FIG. 3, one pixel area is illustrated, which is formed by the intersection of the two first data lines 311 and the two first scanning lines 321.

Still referring to FIG. 3, the pixel area has pixels (not labeled) disposed therein. The pixel includes a self-luminous circuit (not labeled) which includes a plurality of first TFT devices (not shown in FIG. 3) and one self-luminous device (not shown).

It should be noted that, in FIG. 3, the first TFT device and the self-luminous device are not presented independently, but are uniformly illustrated as one display pixel function block 330.

In some embodiments, the display pixel function block 330, the first data lines 311, the first scanning lines 321, a power line 350, a ground line 360, and connection lines among them belong to the self-luminous circuit.

A source (or a drain) of one of the first TFT devices is electrically connected to with the first data lines 311. A drain (or a source) of one of the first TFT devices is electrically connected with the self-luminous device. The first scanning line 321 is electrically connected with a gate of at least one of the first TFT devices. Through the above electrical connections, the first data lines 311 and the first scanning line 321 can be used to perform refresh for display signal to the self-luminous circuit.

Still referring to FIG. 3, the self-luminous display array substrate further includes a plurality of second data lines 312 and a plurality of second scanning lines 322. One second data line 312 and one second scanning line 322 are shown in FIG. 3 for representation.

In some embodiments, the second data line 312 is disposed in parallel with the first data lines 311, and the second scanning line 322 is disposed in parallel with the first scanning line 321.

Still referring to FIG. 3, in some embodiments, an optical fingerprint sensing circuit (not labeled) may be further disposed in at least a portion of the pixels. The pixels in the pixel area shown in FIG. 3 have the optical fingerprint sensing circuit disposed therein.

The optical fingerprint sensing circuit includes a photosensitive device 370 and a second TFT device 380. The photosensitive device 370 includes a first electrode (not labeled) and a second electrode (not labeled). The first electrode of the photosensitive device 370 is electrically connected with a source (or a drain) of the second TFT device 380. The second data line 312 is electrically connected with the drain (or the source) of the second TFT device 380. The second scanning line 322 is electrically connected with the gate of the second TFT device 380.

Still referring to FIG. 3, in some embodiments, the photosensitive device 370 may be a PIN photodiode or a PN photodiode, and thus the first and second electrodes are the two electrodes of the photodiode, respectively.

Still referring to FIG. 3, the self-luminous display array substrate further is includes a common electrode line 340, a power line 350 and a ground line 360. The second electrode of the photosensitive device 370 is electrically connected with the common electrode line 340. Corresponding structures of the display pixel function block 330 are respectively electrically connected with the power line 350 and the ground line 360.

Still referring to FIG. 3, the self-luminous display array substrate further includes a storage capacitor 390. One electrode of the storage capacitor 390 together with the first electrode of the photosensitive device 370 is electrically connected with the source or the drain of the second TFT device 380. The other electrode of the storage capacitor 390 is electrically connected with the ground line 360. In some embodiments, the ground line 360 in the self-luminous circuit serves as a common electrode of the storage capacitor (i.e., the ground line 360 is used to provide a constant potential to a pole of the storage capacitor 390).

In the self-luminous display array substrate provided in the embodiments, the other electrode of the photosensitive device 370 is electrically connected with the common electrode line 340, and the other electrode of the storage capacitor 390 is electrically connected with the ground line 360, which simplifies a connection structure of the storage capacitor and design.

From above, the photosensitive device 370, the second TFT device 380, the storage capacitor 390, the second data lines 312, the second scanning lines 322, the ground line 360, and connection lines among them belong to the optical fingerprint sensing circuit. The ground line 360 is shared by the optical fingerprint sensing circuit and the self-luminous circuit. Therefore, it does not only provide ground for the self-luminous device of the self-luminous circuit but also provides a constant potential to a pole of the storage capacitor 390.

More details about structures, properties and advantages of the self-luminous display array substrate can be found in the above descriptions of the foregoing embodiments.

In an embodiment, another self-luminous display array substrate is provided.

Referring to FIG. 4, FIG. 4 schematically illustrates a partial top view of a self-luminous display array substrate according to an embodiment. The self-luminous display array substrate includes a plurality of first data lines 411 and a plurality of scanning lines 421. In FIG. 4, two first data lines 411 and two scanning lines 421 are illustrated for representation. The first data lines 411 and the scanning lines 421 extend along different axial directions, as shown in FIG. 4.

In some embodiments, as shown in FIG. 4, the two first data lines 411 are parallel with each other, and the two scanning lines 421 are parallel with each other.

Still referring to FIG. 4, the first data lines 411 and the scanning lines 421 intersect to form a plurality of pixel areas (not labeled). In FIG. 4, one pixel area is illustrated, which is formed by the intersection of the two first data lines 411 and the two scanning lines 421.

Still referring to FIG. 4, the pixel area has pixels (not labeled) disposed therein. The pixel includes a self-luminous circuit (not labeled) which includes a plurality of first TFT devices (not shown in FIG. 4) and one self-luminous device (not shown).

It should be noted that, in FIG. 4, the first TFT device and the self-luminous device are not presented independently, but are uniformly illustrated as one display pixel function block 430.

In some embodiments, the display pixel function block 430, the first data lines 411, the scanning lines 421, a power line 450, a ground line 460, and connection lines among them constitute the self-luminous circuit.

A source (or a drain) of one of the first TFT devices is electrically connected with the first data lines 411. A drain (or a source) of one of the first TFT devices is electrically connected with the self-luminous device. The scanning lines 421 are electrically connected with a gate of at least one of the first TFT devices. Through the above electrical connections, the first data lines 411 and the scanning line 421 can be used to perform refresh for display signal to the self-luminous circuit.

Still referring to FIG. 4, the self-luminous display array substrate further includes a plurality of second data lines 412. One second data line 412 is shown in FIG. 4 for representation.

In some embodiments, the second data line 412 is disposed in parallel with to the first data lines 411.

Still referring to FIG. 4, in some embodiments, an optical fingerprint sensing circuit (not labeled) may be further disposed in at least a portion of the pixels. The pixels in the pixel area shown in FIG. 4 have the optical fingerprint sensing circuit disposed therein.

The optical fingerprint sensing circuit includes a photosensitive device 470 and a second TFT device 480. The photosensitive device 470 includes a first electrode (not labeled) and a second electrode (not labeled). The first electrode of the photosensitive device 470 is electrically connected with a source (or a drain) of the second TFT device 480. The second data line 412 is electrically connected with the drain (or the source) of the second TFT device 480. The scanning line 421 is electrically connected with the gate of the second TFT device 480. That is, the scanning line 421 is not only electrically connected with the gate of the first TFT device but also electrically connected with the gate of the second TFT device 480, so that display signal refresh to the self-luminous circuit and fingerprint signal acquisition from the optical fingerprint sensing circuit can be performed at the same time subsequently.

Still referring to FIG. 4, in some embodiments, the photosensitive device 470 may be a PIN photodiode or a PN photodiode, and thus the first and second electrodes are the two electrodes of the photodiode, respectively.

Still referring to FIG. 4, the self-luminous display array substrate further includes a storage capacitor 490 which is connected in parallel with the photosensitive device 470. One electrode of the storage capacitor 490 together with the first electrode of the photosensitive device 470 is electrically connected with the source or the drain of the second TFT device 480.

Still referring to FIG. 4, the self-luminous display array substrate further includes a common electrode line 440. The other electrode of the storage capacitor 490 together with the second electrode of the photosensitive device 470 is electrically connected with the common electrode line 440, and the second electrode of the photosensitive device 470 is electrically connected with the common electrode line 440, so that the photosensitive device 470 can be biased with a negative voltage using the common electrode 440, i.e., the photosensitive device 470 is reversely biased.

From above, the photosensitive device 470, the second TFT device 480, the storage capacitor 490, the second data lines 412, the scanning lines 421, and connection lines among them constitute the optical fingerprint sensing circuit. The scanning lines 421 are shared by the optical fingerprint sensing circuit and the self-luminous circuit, and do not only control the refresh for display signals to the self-luminous circuit, but also control the acquisition of fingerprint signals from the photosensitive device 470.

Still referring to FIG. 4, the self-luminous display array substrate further includes a power line 450 and a ground line 460. Corresponding structures (not specifically shown in FIG. 4) of the display pixel function block 430 are respectively electrically connected with the power line 450 and the ground line 460.

In some embodiments, the other electrode of the photosensitive device may be electrically connected with the common electrode line independently, and the other electrode of the storage capacitor may be electrically connected with the power line or the ground line.

In the self-luminous display array substrate provided in the embodiments, the self-luminous circuit and the optical fingerprint sensing circuit are disposed in the same pixel (i.e., disposed in the same pixel area), and the self-luminous device in the self-luminous circuit is electrically connected with the first data lines 411 and the scanning lines 421 via the first TFT device, and the photosensitive device 470 in the optical fingerprint sensing circuit is electrically connected with the second data lines 412 and the scanning lines 421 via the second TFT device 480, so that the self-luminous display array substrate does not only support a display function, but also can acquire a fingerprint image pressed on a display screen which is provided with the self-luminous display array substrate based on optical principle. That is, the self-luminous display array substrate can be used to acquire the fingerprint image. In this way, functions and an integration level of the self-luminous display array substrate may be increased.

Further, in the self-luminous display array substrate provided in the embodiments, both the self-luminous circuit and the optical fingerprint sensing circuit are electrically connected with the scanning lines 421, that is, the two circuits share the scanning lines 421. The structure reduces the number of scanning lines and further improves the overall structure of the self-luminous display array substrate.

More details about structures, properties and advantages of the self-luminous display array substrate can be found in the above descriptions of the foregoing embodiments.

In an embodiment of the present disclosure, a using method of the self-luminous display array substrate of the embodiment shown in FIG. 4 is provided.

As the self-luminous circuit and the optical fingerprint sensing circuit share the scanning lines 421, when the first data lines 411 and the scanning lines 421 are used to perform refresh for display signal to the self-luminous circuit, the second data lines 412 and the scanning lines 421 are used to acquire fingerprint image data from the optical fingerprint sensing circuit (specifically, the photosensitive device 470).

Specifically, when fingerprint acquisition is not required, the self-luminous circuits and the optical fingerprint sensing circuits in a particular row of pixels are controlled to be turned on at the same time by the scanning lines 421, and refresh for display signal is performed to the self-luminous circuits by using the first data lines 411. However, an external control chip does not acquire fingerprint image information in the optical fingerprint sensing circuit via the second data lines 412, that is, the optical fingerprint sensing circuit is in a useless state. The scanning lines 421 scan line by line, and finally the refresh for display signal is performed to the self-luminous circuits in all the pixels by using the first data lines 411.

When fingerprint acquisition is required, the self-luminous circuits and the optical fingerprint sensing circuits in a particular row of pixels are controlled to be turned on at the same time by the scanning lines 421, refresh for display signal is performed to the self-luminous circuits by using the first data lines 411, and the external control chip acquires fingerprint image information in the optical fingerprint sensing circuits via the second data lines 412. The scanning lines 421 scan line by line, and finally the refresh for display signal is performed to the self-luminous circuits in all the pixels by using the first data lines 411, and acquisition of the fingerprint image information is performed to the optical fingerprint sensing circuits in all the pixels by using the second data lines 412.

In the above method, no extra time is required for acquiring the fingerprint image data. Therefore, the display function of the self-luminous display array is substrate may work without influence, and it only needs to be guaranteed that the two functions can be implemented simultaneously. Therefore, good integration effect may be provided.

In an embodiment, another self-luminous display array substrate is provided.

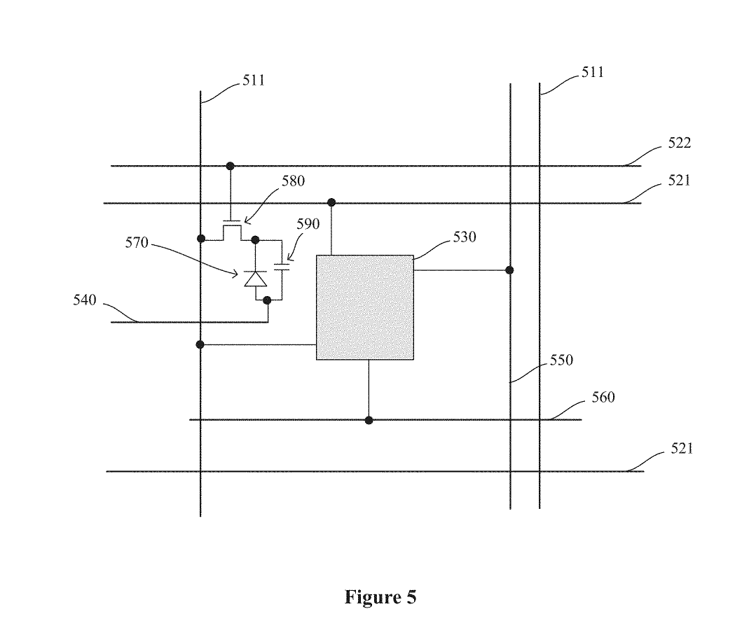

Referring to FIG. 5, FIG. 5 schematically illustrates a partial top view of a self-luminous display array substrate according to an embodiment. The self-luminous display array substrate includes a plurality of data lines 511 and a plurality of first scanning lines 521. In FIG. 5, two data lines 511 and two first scanning lines 521 are illustrated for representation. The data lines 511 and the first scanning lines 521 extend along different axial directions, as shown in FIG. 5.

As shown in FIG. 5, the two data lines 511 are parallel with each other, and the two first scanning lines 521 are parallel with each other.

Still referring to FIG. 5, the data lines 511 and the first scanning lines 521 intersect to form a plurality of pixel areas (not labeled). In FIG. 5, one pixel area is illustrated, which is formed by the intersection of the two data lines 511 and the two first scanning lines 521.

Still referring to FIG. 5, the pixel area has pixels (not labeled) disposed therein. The pixel includes a self-luminous circuit (not labeled) which includes a plurality of first TFT devices (not shown in FIG. 5) and one self-luminous device (not shown).

It should be noted that, in FIG. 5, the first TFT device and the self-luminous device are not presented independently, but are uniformly illustrated as one display pixel function block 530.

In some embodiments, the display pixel function block 530, the data lines 511, the first scanning lines 521, a power line 550, a ground line 560, and connection lines among them belong to the self-luminous circuit.

A source (or a drain) of one of the first TFT devices is electrically connected with the data lines 511. A drain (or a source) of one of the first TFT devices is electrically connected with the self-luminous device. The first scanning lines 521 are electrically connected with a gate of at least one of the first TFT devices. Through the above electrical connections, the data lines 511 and the first scanning line 521 can be used to perform refresh for display signal to the self-luminous circuit.

Still referring to FIG. 5, the self-luminous display array substrate further includes a plurality of second scanning lines 522. One second scanning line 522 is shown in FIG. 5 for representation.

In some embodiments, the second scanning line 522 is disposed in parallel with the first scanning lines 521.

Still referring to FIG. 5, in some embodiments, an optical fingerprint sensing circuit (not labeled) may be further disposed in at least a portion of the pixels. The pixels in the pixel area shown in FIG. 5 have the optical fingerprint sensing circuit disposed therein.

The optical fingerprint sensing circuit includes a photosensitive device 570 and a second TFT device 580. The photosensitive device 570 includes a first electrode (not labeled) and a second electrode (not labeled). The first electrode of the photosensitive device 570 is electrically connected with a source (or a drain) of the second. TFT device 580. The second scanning line 522 is electrically connected with the gate of the second TFT device 580. The data line 511 is electrically connected with the drain (or the source) of the second TFT device 580. That is, the data line 511 is not only electrically connected with the source or the drain of the first TFT device but also electrically connected with the source or the drain of the second. TFT device 580. Therefore, refresh for display signal to the self-luminous circuit and fingerprint signal acquisition from the optical fingerprint sensing circuit need to be performed at different times subsequently.

Still referring to FIG. 5, in some embodiments, the photosensitive device 570 may be a PIN photodiode or a PN photodiode, and thus the first and second electrodes are the two electrodes of the photodiode, respectively.

Still referring to FIG. 5, the self-luminous display array substrate further includes a storage capacitor 590 which is connected in parallel with the photosensitive device 570. One electrode of the storage capacitor 590 together with the first electrode of the photosensitive device 570 is electrically connected with the source or the drain of the second TFT device 580.

Still referring to FIG. 5, the self-luminous display array substrate further includes a common electrode line 540. The other electrode of the storage capacitor 590 together with the second electrode of the photosensitive device 570 is electrically connected with the common electrode line 540, and the second electrode of the photosensitive device 570 is electrically connected with the common electrode line 540, so that the photosensitive device 570 can be biased with a negative voltage using the common electrode line 540, i.e., the photosensitive device 570 is reversely biased.

From above, the photosensitive device 570, the second TFT device 580, the storage capacitor 590, the data lines 511, the second scanning lines 522, and connection lines among them constitute the optical fingerprint sensing circuit. The data lines 511 are shared by the optical fingerprint sensing circuit and the self-luminous circuit, and do not only control the refresh for display signals to the self-luminous circuit, but also control the acquisition of fingerprint signals from the photosensitive device 570.

Still referring to FIG. 5, the self-luminous display array substrate further includes a power line 550 and a ground line 560. Corresponding structures (not specifically shown in FIG. 5) of the display pixel function block 530 are respectively electrically connected with the power line 550 and the ground line 560.

In some embodiments, the other electrode of the photosensitive device may be electrically connected with the common electrode line independently, and the other electrode of the storage capacitor may be electrically connected with the power ne or the ground line.

In the self-luminous display array substrate provided in the embodiments, the self-luminous circuit and the optical fingerprint sensing circuit are disposed in the same pixel (i.e., disposed in the same pixel area), and the self-luminous device in the self-luminous circuit is electrically connected with the data lines 511 and the first scanning lines 521 via the first TFT device, and the photosensitive device 570 in the optical fingerprint sensing circuit is electrically connected with the data lines 511 and the second scanning lines 522 via the second TFT device 580, so that the self-luminous display array substrate does not only support a display function, but also can acquire a fingerprint image pressed on a display screen which is provided with the self-luminous display array substrate based on optical principle. That is, the self-luminous display array substrate can be used to acquire the fingerprint image. In this way, functions and an integration level of the self-luminous display array substrate may be increased.

Further, in the self-luminous display array substrate provided in the embodiments, both the self-luminous circuit and the optical fingerprint sensing circuit are electrically connected with the data lines 511, that is, the two circuits share the data lines 511. The structure reduces the number of data lines and further improves the overall structure of the self-luminous display array substrate.

More details about structures, properties and advantages of the self-luminous display array substrate can be found in the above descriptions of the foregoing embodiments.

In an embodiment of the present disclosure, a using method of the self-luminous display array substrate of the embodiment shown in FIG. 5 is provided.

As the self-luminous circuit and the optical fingerprint sensing circuit share the data lines 511, a process of using the data lines 511 and the first scanning lines 521 to perform refresh for display signal to the self-luminous circuit and a process of using the data lines 511 and the second scanning lines 522 to acquire fingerprint image data from the optical fingerprint sensing circuit (specifically, the photosensitive device 570) may be performed at different times.

In some embodiments, the data lines 511 and the first scanning lines 521 are used to perform refresh for display signal to the self-luminous circuit, and then the data lines 511 and the second scanning lines 522 are used to acquire fingerprint mage data from the optical fingerprint sensing circuit (specifically, the photosensitive device 570).

Specifically, when fingerprint acquisition is not required, the self-luminous circuits in a particular row (or more than one rows) of pixels are controlled to be turned on by the first scanning lines 521, and refresh for display signal is performed to the self-luminous circuits by using the data lines 511 (i.e., the data lines and the first scanning lines are used to perform once refresh for display signal to a portion of the self-luminous circuits). However, an external control chip does not control the optical fingerprint sensing circuits in any row to he turned on via the second scanning lines 522, that is, the optical fingerprint sensing circuit is in a useless state. The first scanning lines 521 scan line by line, and finally the refresh for display signal is performed to the self-luminous circuits in all the pixels by using the data lines 511.

When fingerprint acquisition is required, the self-luminous circuits in a. particular row (or more than one rows) of pixels are controlled to be turned on by the first scanning lines 521, refresh for display signal is performed to the self-luminous circuits by using the data lines 511, the second scanning lines 522 control the optical fingerprint sensing circuits in a particular row (or more than one rows) to he turned on, and the external control chip acquires fingerprint image information in the optical fingerprint sensing circuits via the data lines 511. The first scanning lines 521 and the second scanning lines 522 perform interleaved scanning line by line, and finally the refresh for display signal is performed to the self-luminous circuits in all the pixels by using the data lines 511, and acquisition of the fingerprint image information is performed from the optical fingerprint sensing circuits in all the pixels by using the data lines 511.

In the above method, once display signals of a row of pixels are refreshed, fingerprint image data of a row of pixels is acquired. Therefore, the time for refreshing each display signal is relatively reduced. Besides, the method can ensure that a refreshing rate of the display signals does not change.

In an embodiment of the present disclosure, another using method of the self-luminous display array substrate of the embodiment shown in FIG. 5 is provided. Similarly, display signal refreshing and fingerprint image data acquisition may be performed at different times.

In some embodiments, after every N frames of display information are refreshed (N is an integer greater than 1, and during line-by-line scanning, finishing refreshing display information to all the rows of pixels represents finishing refresh for display information of one frame), fingerprint acquisition of one frame is performed (during line-by-line scanning, finishing fingerprint information acquisition from the optical fingerprint sensing circuit of all the rows of pixels represents finishing fingerprint acquisition of one frame). In the display information refresh of each frame, the data lines 511 and the first scanning lines 521 are used to refresh display signals to the self-luminous circuit line by line. During a fingerprint acquisition period, the data lines 511 and the second scanning lines 522 are used to acquire fingerprint image data line by line from the optical fingerprint sensing circuit (specifically, the photosensitive device 570).

In some embodiments, fingerprint acquisition of one frame is performed after every N frames of display information are refreshed. The N frames for display information refresh and the one frame for fingerprint acquisition may be regarded as a large repeated period and serves as a working period of the self-luminous display array substrate.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure.

What is claimed is:

1. A self-luminous display array substrate, comprising:
a plurality of first data lines; and
a plurality of first scanning lines,
wherein the plurality of first data lines and the plurality of first scanning lines intersect to form a plurality of pixel areas which have pixels disposed therein, each pixel comprises a self-luminous circuit which comprises at least one first TFT device and at least one self-luminous device, the first data lines are electrically connected with a source or a drain of at least one of the first TFT devices, and the first scanning lines are electrically connected with a gate of at least one of the first TFT devices,
wherein the self-luminous display array substrate further comprises a plurality of second data lines and a plurality of second scanning lines, at least a portion of the pixels have an optical fingerprint sensing circuit which comprises at least one photosensitive device and at least one second TFT device, the photosensitive device comprises a first electrode and a second electrode, the first electrode is electrically connected with a source or a drain of one second TFT device, the second data lines are electrically connected with a drain or a source of one second TFT device, and the second scanning lines are electrically connected with a gate of at least one of the second TFT devices.

2. The self-luminous display array substrate according to claim 1, further comprising a storage capacitor which is connected with the photosensitive device in parallel and a common electrode line, wherein one electrode of the storage capacitor and the first electrode of the photosensitive device are electrically connected with the source or the drain of the one second TFT device, and the other electrode of the storage capacitor and the second electrode of the photosensitive device are electrically connected with the common electrode line.

3. The self-luminous display array substrate according to claim 1, further comprising a common electrode line, a power line, a ground line and a storage capacitor, wherein the second electrode of the photosensitive device is electrically connected with the common electrode line, one electrode of the storage capacitor and the first electrode of the photosensitive device are electrically connected with the source or the drain of the one second TFT device, and the other electrode of the storage capacitor is electrically connected with the power line or the ground line.

4. The self-luminous display array substrate according to claim 1, wherein light emitted from the self-luminous circuit serves as light for fingerprint acquisition of the optical fingerprint sensing circuit.

5. A self-luminous display array substrate, comprising:
a plurality of first data lines; and
a plurality of scanning lines,
wherein the plurality of first data lines and the plurality of scanning lines intersect to form a plurality of pixel areas which have pixels disposed therein, each pixel comprises a self-luminous circuit which comprises at least one first TFT device and at least one self-luminous device, the first data lines are electrically connected with a source or a drain of at least one of the first TFT devices, and the scanning lines are electrically connected with a gate of at least one of the first TFT devices,
wherein the self-luminous display array substrate further comprises a plurality of second data lines, at least a portion of the pixels have an optical fingerprint sensing circuit which comprises at least one photosensitive device and at least one second TFT device, the photosensitive device comprises a first electrode and a second electrode, the first electrode is electrically connected with a source or a drain of one second TFT device, the second data lines are electrically connected with a drain or a source of one second TFT device, and the scanning lines are electrically connected with a gate of at least one of the second TFT devices.

6. The self-luminous display array substrate according to claim 5, further comprising a storage capacitor which is connected with the photosensitive device in parallel and a common electrode line, wherein one electrode of the storage capacitor and the first electrode of the photosensitive device are electrically connected with the source or the drain of the one second TFT device, and the other electrode of the storage capacitor and the second electrode of the photosensitive device are electrically connected with the common electrode line.

7. The self-luminous display array substrate according to claim 5, further comprising a common electrode line, a power line, a ground line and a storage capacitor, wherein the second electrode of the photosensitive device is electrically connected with the common electrode line, one electrode of the storage capacitor and the first electrode of the photosensitive device are electrically connected with the source or the drain of the one second TFT device, and the other electrode of the storage capacitor is electrically connected with the power line or the ground line.

8. The self-luminous display array substrate according to claim 5, wherein light emitted from the self-luminous circuit serves as light for fingerprint acquisition of the optical fingerprint sensing circuit.

9. A using method of the self-luminous display array substrate according to claim 5, wherein the first data lines and the scanning lines are used to perform refresh for display signal to the self-luminous circuit, and the second data lines and the scanning lines are used to acquire fingerprint image data from the optical fingerprint sensing circuit.

10. A self-luminous display array substrate, comprising:
a plurality of data lines; and
a plurality of first scanning lines,
wherein the plurality of data lines and the plurality of first scanning lines intersect to form a plurality of pixel areas which have pixels disposed therein, each pixel comprises a self-luminous circuit which comprises at least one first TFT device and at least one self-luminous device, the data lines are electrically connected with a source or a drain of at least one of the first TFT devices, and the first scanning lines are electrically connected with a gate of at least one of the first TFT devices,
wherein the self-luminous display array substrate further comprises a plurality of second scanning lines, at least a portion of the pixels have an optical fingerprint sensing circuit which comprises at least one photosensitive device and at least one second TFT device, the photosensitive device comprises a first electrode and a second electrode, the first electrode is electrically connected with a source or a drain of one second TFT device, the data lines are electrically connected with a drain or a source of one second TFT device, and the second scanning lines are electrically connected with a gate of at least one of the second TFT devices.

11. The self-luminous display array substrate according to claim 10, further comprising a storage capacitor which is connected with the photosensitive device in parallel and a common electrode line, wherein one electrode of the storage capacitor and the first electrode of the photosensitive device are electrically connected with the source or the drain of the one second TFT device, and the other electrode of the storage capacitor and the second electrode of the photosensitive device are electrically connected with the common electrode line.

12. The self-luminous display array substrate according to claim 10, further comprising a common electrode line, a power line, a ground line and a storage capacitor, wherein the second electrode of the photosensitive device is electrically connected with the common electrode line, one electrode of the storage capacitor and the first electrode of the photosensitive device are electrically connected with the source or the drain of the one second TFT device, and the other electrode of the storage capacitor is electrically connected with the power line or the ground line.

13. The self-luminous display array substrate according to claim 10, wherein light emitted from the self-luminous circuit serves as light for fingerprint acquisition of the optical fingerprint sensing circuit.

14. A using method of the self-luminous display array substrate according to claim 10, wherein the data lines and the first scanning lines are used to perform once refresh for display signal to a portion of the self-luminous circuits, and then the data lines and the second scanning lines are used to acquire fingerprint image data from a portion of the optical fingerprint sensing circuits; or
the data lines and the second scanning lines are used to acquire fingerprint image data from a portion of the optical fingerprint sensing circuits, and then the data lines and the first scanning lines are used to perform once refresh for display signal to a portion of the self-luminous circuits.

15. A using method of the self-luminous display array substrate according to claim 10, wherein the data lines and the first scanning lines are used to perform at least once refresh for display signal to all the self-luminous circuits, and then the data lines and the second scanning lines are used to acquire fingerprint image data from all the optical fingerprint sensing circuits.

16. The self-luminous display array substrate according to claim 2, wherein light emitted from the self-luminous circuit serves as light for fingerprint acquisition of the optical fingerprint sensing circuit.

17. The self-luminous display array substrate according to claim 3, wherein light emitted from the self-luminous circuit serves as light for fingerprint acquisition of the optical fingerprint sensing circuit.

18. The self-luminous display array substrate according to claim 6, wherein light emitted from the self-luminous circuit serves as light for fingerprint acquisition of the optical fingerprint sensing circuit.

19. The self-luminous display array substrate according to claim 7, wherein light emitted from the self-luminous circuit serves as light for fingerprint acquisition of the optical fingerprint sensing circuit.

20. The self-luminous display array substrate according to claim 11, wherein light emitted from the self-luminous circuit serves as light for fingerprint acquisition of the optical fingerprint sensing circuit.
